(19) United States
(12) Patent Application Publication
(10) Pub. No.: US 2020/0013127 A1
(43) Pub. Date: Jan. 9, 2020

(54) SYSTEM AND METHOD OF OPTIMIZING BUILDING PLANS

(71) Applicant: TAMA FIX LTD., Hod HaSharon (IL)

(72) Inventors: Lior GOZES, Givataim (IL); Eliran SIMIONI, Hod Hasharon (IL)

(73) Assignee: TAMA FIX LTD., Hod HaSharon (IL)

(21) Appl. No.: 16/487,841

(22) PCT Filed: Feb. 22, 2018
(86) PCT No.: PCT/IL2018/050203

§ 371 Date: Aug. 22, 2019

Related U.S. Application Data
(60) Provisional application No. 62/462,413, filed on Feb. 23, 2017.

(51) Int. Cl. G06Q 50/16; G06F 17/50; G06Q 10/06

(52) U.S. Cl. CPC G06Q 50/165; G06Q 10/063118; G06F 17/5004

(57) ABSTRACT

A method of generating building work plans, may include: selecting an area for evaluating an urban renovation project therein; receiving, by a controller, urban renovation data from a first database; identifying, by the controller, at least one building within the selected area, that is suitable for urban renovation by comparing data related to the at least one building with the urban renovation data; receiving, by the controller, from a second database, current architectural data for the at least one building; receiving, by the controller, data related to building rights and requirements, from a third database, for the at least one building; combining, by the controller, the received data related to building rights and requirements, architectural data and urban renovation data; and generating at least one work plan from the combined data.

### FIELD OF THE INVENTION

The present invention relates generally to the field of urban planning, and more specifically to management of urban renovation projects.

### BACKGROUND OF THE INVENTION

Urban renovation processes take place in almost every city in the world. Such processes usually involve, reconstructing or destroying and replacing old buildings with new modern ones. Selecting old buildings for the urban renovation process and planning the new buildings must take into account numerous amount of different information from various sources. For example, the information may include architectural information regarding the development rights and regulations, economical information related to the building costs, taxes, funding, revenue etc. and legal information regarding the legal rights of landlords, the tenants living in the old buildings, the construction company building the new buildings and the like.

Currently, each step of the urban renovation process is conducted manually by one or more different professionals. For example, several architects and engineers plan the constructions plans, account managers and economists study the economical information and lawyers study the legal rights. Each of the professionals works separately, disregarding the considerations taken by the other professionals. This may lead to limited and sometimes completely wrong estimation regarding the feasibility of an urban renovation project for a particular building, street, area or the entire city. There is a need for a computerized system that will receive all the necessary information from different databases and will replace the work of all the various professional while taking into account the mutual effect of all the considerations from all aspects of the urban renovation process on the final plans.

### SUMMARY OF THE INVENTION

Embodiments of the present invention disclose a method of generating building work plans, including the steps of: selecting an area for evaluating an urban renovation project therein; receiving, by a controller, urban renovation data from a first database; identifying, by the controller, at least one building within the selected area, that is suitable for urban renovation by comparing data related to the at least one building with the urban renovation data; receiving, by the controller, from a second database, current architectural data for the at least one building; receiving, by the controller, data related to building rights and requirements, from a third database, for the at least one building; and generating at least one work plan from the received data.

According to some embodiments, the urban renovation data may include at least one of: areas selected for urban renovation projects; criteria for selection of these areas; a maximal permitted floor-area ratio that may be added to buildings according to renovation plans; a maximal number of floors permitted to be added according to renovation plans; and specific requirements imposed by building and planning committees.

According to some embodiments, the data related to building rights and requirements includes at least one of: the maximal floor-area ratio, the maximal number of floors allowed, parking space requirements, and minimal required distance from neighboring buildings.

According to some embodiments, generating at least one work plan includes determining, by the controller the number of floors in each of the at least one building.

According to some embodiments, generating at least one work plan comprises determining, by the controller, the number of apartments in each floor of the at least one building.

According to some embodiments, generating at least one work plan comprises determining the number and location of parking spaces of the at least one building.

According to some embodiments, generating at least one work plan comprises generating detailed construction plans for each floor in the at least one building.

According to some embodiments, the method of generating building work plans may further include: receiving, by the controller, cost-related data from at least a fourth database; combining the cost-related data with data of at least one generated work plan; and producing, by the controller, at least one economic plan from the combined data. The economic plan may include economic information pertaining to the perspective of different stakeholders, including for example: tenants, apartment owners, landlords, building contractors and building entrepreneurs.

According to some embodiments, the cost-related data may include at least one of: building costs, data related to taxation, funding costs and project revenue.

According to some embodiments, the cost-related data may further include prices of apartments in an area comprising the at least one selected building.

According to some embodiments, the method may further include updating the prices of the apartments in the area based on information received from at least one of a web site and a social network.

According to some embodiments, the economic plan may include information relating to at least one of: economic feasibility of a potential urban renovation project; economic profitability of at least one potential urban renovation project; cost of renovation; present rent income from a property; and present valuation of a property.

According to some embodiments, the method may further include: combining, by the controller cost-related data with data of at least one generated work plan; and analyzing the combined data, to generate at least one economic plan that comprises at least one of: a prediction of expected rent income in the future, following an urban renovation; and a prediction of expected evaluation of a property in the future, following urban renovation.

According to some embodiments, the economic plan may include: an evaluation of whether compensation is due to one or more of the stakeholders; evaluation of the compensation cost; and at least one alternative for compensation.

According to some embodiments, the cost-related data may include socioeconomic data relating to the population in the selected area, and the economic plan may include an evaluation of socioeconomic parameters pertaining to the population before, during and after applying an urban renovation project.

According to some embodiments, the socioeconomic parameters may include at least one of: the population's ability to withstand payments; the population's standard of living; and an expected influx of population to the renovated area following the renovation.

According to some embodiments, the method further includes the steps of: receiving, by the controller, an update to the cost-related data; and updating, by the controller, at least one generated work plan based on the updated cost-related data.

According to some embodiments, the method may further include iterative optimization of the work plan according to at least one optimization criterion.

According to some embodiments, the optimization may further include the steps of: receiving, from a user, at least one optimization criterion; generating by the controller a plurality of alternative work plans; combining data of at least one alternative generated work plan with at least one of: respective cost-related data and respective socioeconomic data; generating at least one economic plan, associated with at least one alternative work plan, wherein said at least one economic plan comprises an assessment associated with the at least one optimization criterion; and selecting at least one work plan of the plurality of alternative work plans according to assessment associated with the at least one optimization criterion.

According to some embodiments, optimizing, by the controller, at least one generated work plan may further include the steps of: combining the generated work plan with stakeholder-related data; and producing, by the controller, at least one alternative work plan, that is optimized according to the stakeholder-related data.

According to some embodiments, the method may further include updating at least one economic plan according to data of at least one generated work plan.

According to some embodiments, the method may further include the steps of: updating by the controller at least one cost-related data element; and iteratively optimizing, by the controller, generated work plans for at least one building that is affected by the updating of the cost-data.

According to some embodiments, the method may further include: selecting, by a user at least one of a preferred work plan and a preferred economic plan; and producing, by the controller, a tender from the selected plans, for implementing the work plans, and selecting the best offer based on predetermined parameters, wherein said parameters are selected among a list comprising cost, delivery time and quality demands.

According to some embodiments, the economic plans may further include development rights attributed to at least one specific stakeholder.

According to some embodiments, the controller may be further configured to display the economic plans on a website, and enable users to trade on such development rights with other users, according to their manifestation in the economic plans.

Embodiments of the present invention disclose a system of generating building work plans, including at least one of: at least one non-transitory memory medium, configured to store instructions to perform operations and/or processes; and a controller associated with said memory medium, and configured to execute said instructions. According to some embodiments, upon execution of the instructions, the controller may be configured to: receive from a user a selection of an area for evaluating an urban renovation project therein; receive, urban renovation data from a first database; identify at least one building within the selected area, that is suitable for urban renovation by comparing data related to the at least one building with the urban renovation data; receive from a second database, current architectural data for the at least one building; receive data related to building rights and requirements, from a third database, for the at least one building; and generate from the received data related to building rights and requirements, architectural data and urban renovation data to at least one work plan from the received data.

### BRIEF DESCRIPTION OF THE DRAWINGS

The subject matter regarded as the invention is particularly pointed out and distinctly claimed in the concluding portion of the specification. The invention, however, both as to organization and method of operation, together with objects, features, and advantages thereof, may best be understood by reference to the following detailed description when read with the accompanying drawings in which:

FIG. 1 is a diagrammatic representation of a system for generating conceptual work plans and/or optimizing urban renovation plans, according to some embodiments of the invention;

FIG. 2 is a flowchart of a method of generating conceptual work plans according to some embodiments of the invention; and

FIGS. 3A-3D are illustrations of conceptual work plans according to some embodiments of the inventions.

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

### DETAILED DESCRIPTION OF THE PRESENT INVENTION

In the following detailed description, numerous specific details are set forth in order to provide a thorough understanding of the invention. However, it will be understood by those skilled in the art that the present invention may be practiced without these specific details. In other instances, well-known methods, procedures, and components, modules, units and/or circuits have not been described in detail so as not to obscure the invention. Some features or elements described with respect to one embodiment may be combined with features or elements described with respect to other embodiments. For the sake of clarity, discussion of same or similar features or elements may not be repeated.

Although embodiments of the invention are not limited in this regard, discussions utilizing terms such as, for example, “processing,” “computing,” “calculating,” “determining,” “establishing”, “analyzing”, “checking”, or the like, may refer to operation(s) and/or process(es) of a computer, a computing platform, a computing system, or other electronic computing device, that manipulates and/or transforms data represented as physical (e.g., electronic) quantities within the computer's registers and/or memories into other data similarly represented as physical quantities within the computer's registers and/or memories or other information non-transitory storage medium that may store instructions to perform operations and/or processes. Although embodiments of the invention are not limited in this regard, the terms “plurality” and “a plurality” as used herein may include, for example, “multiple” or “two or more”. The terms “plurality” or “a plurality” may be used throughout the specification to describe two or more components, devices, elements, units, parameters, or the like. The term set when used herein may include one or more items. Unless explicitly stated, the method embodiments described herein are not constrained to a particular order or sequence. Additionally, some of the described method embodiments or elements thereof can occur or be performed simultaneously, at the same point in time, or concurrently.

The term “work plan” is henceforth used throughout this document to refer to any type of plan for urban renovation or reconstruction that may be obtained by the disclosed system and method, and may apply to any scale of constructed entity, including for example: single buildings, a group of buildings in a street, an entire street, an entire neighborhood, an entire city, etc. The term “building work plans” may further refer to any type of conceptual layout plans for buildings and apartments, including for example addition of floors to a building, partition of floors to apartments, etc. The term “infrastructure work plans” may refer to any type of conceptual layout plans for municipal infrastructure (e.g.: power lines and sewer lines), location of community services (e.g. schools and clinics), location of edifices (e.g. offices, commercial areas, etc.).

Some aspects of the invention may be directed to a system and a method of generating and optimizing work plans for urban renovation projects. Additional aspects of the invention may include providing feasibility tests and costs estimation to potential urban renovation projects. The system and method according to some embodiments of the invention may conduct such estimations and may generate work plans for structured elements of any scale, including for example: a single building, several buildings in a street, an entire street, an entire neighborhood and an entire city.

As explained above, the process of urban renovation includes acquisition of different data elements from a large number of sources. These data elements may include an abundance of unassociated information, belong to different offices (e.g.: municipalities, architect firms, engineering firms, building and planning committees, etc.), apply to different disciplines (e.g.: electricity infrastructure plans, and urban development plans), etc. There is great difficulty in acquiring this data, and arranging it in a comprehensive format, that would enable stakeholders (e.g. entrepreneurs, landlords, house owners and residents) to establish a comprehensive picture of their properties current status, let alone derive work plans for performing urban renovation. Furthermore, it is extremely difficult to derive a scheme for optimizing such work plans: each stakeholder refers to different economic, practical and aesthetic properties of the urban renovation plan, and of course different individuals present different sets of needs and interests in relation to an urban renovation plan. Therefore, there is a need for a computerized system that will receive all the necessary information from all relevant data sources, without being reliant on internal communication between different entities and role players, and produce transparent, optimized plans for urban renovation from the viewpoint of every stakeholder in the project.

Embodiments of the present invention disclose a system configured to enable users, including for example building entrepreneurs, apartment owners, landlords, municipalities, and contractors, to: (i)provide at least one address of a building of interest; (ii) generate at least one set of building work plans for the at least one building of interest, that are optimized according to predefined criteria; and (iii) receive cost estimations, and data relating to other economic aspects of the generated plans.

According to some embodiments, the system may collect information from a variety of databases, on-line resources and off-line resources, including for example: local, municipal databases, state or governmental databases, real-estate related websites, construction-related websites and databases, social media websites and the like. The system may be configured to: (i) analyze the collected information; produce at least one work plan, and respective economic estimations for at least one potential urban renovation project; and (ii) present the work plans along with the economic estimations for a user to assess the feasibility and profitability of each work plan.

In some embodiments, the system may be configured to iteratively update work plans and estimations upon receiving new data. For example, the system may predict the revenues from the project at the end of the building process by taking into account future potential competitive projects, including urban renovation projects on a nearby street, at the same neighborhood, at the same city or at a neighboring city.

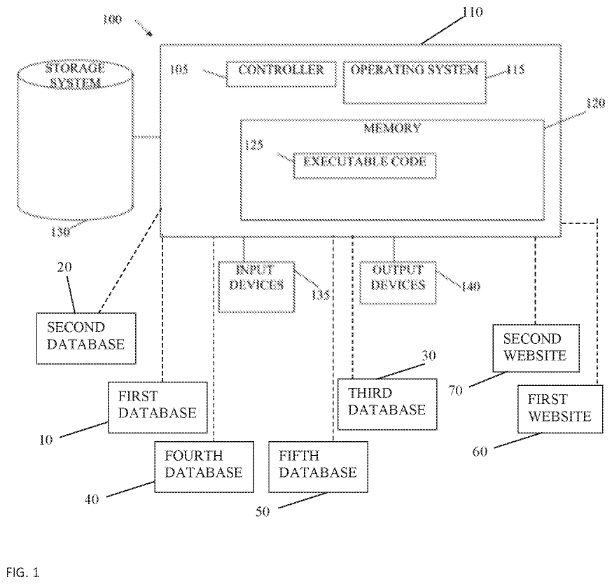

Reference is now made to FIG. 1 which is a diagrammatic representation of a system for generating work plans and/or optimizing urban renovation plans according to some embodiments of the invention. A system 100 may include a server 110 and a storage system 130. System 100 may be configured to receive, via the internet, data related to work plans, data related to urban renovation plans, data related to development rights and requirements, cost-related data, legal information and the like from databases 10-50 and websites 60-70.

Server 110 may include a controller 105 that may be, for example, a central processing unit (CPU), a chip or any suitable computing or computational device, an operating system 115, a memory 120, executable code 125, a storage system 130 that may include input devices 135 and output devices 140. Controller 105 (or one or more controllers or processors, possibly across multiple units or devices) may be configured to carry out methods described herein, and/or to execute or act as the various modules, units, etc. More than one server 110 may be included in, and one or more systems 100 may act as the components of, a system according to embodiments of the invention.

Operating system 115 may be or may include any code segment (e.g., one similar to executable code 125 described herein) designed and/or configured to perform tasks involving coordination, scheduling, arbitration, supervising, controlling or otherwise managing operation of server 110, for example, scheduling execution of software programs or tasks or enabling software programs or other modules or units to communicate. Operating system 115 may be a commercial operating system. It will be noted that an operating system 115 may be an optional component, e.g., in some embodiments, a system may include a computing device that does not require or include an operating system 115. For example, an SEU (Source Edit Utility) may be, or may include, a microcontroller, an application specific circuit (ASIC), a field programmable array (FPGA) and/or system on a chip (SOC) that may be used (e.g., as, or included in, an SEU) without an operating system.

Memory 120 may be or may include, for example, a Random Access Memory (RAM), a read only memory (ROM), a Dynamic RAM (DRAM), a Synchronous DRAM (SD-RAM), a double data rate (DDR) memory chip, a Flash memory, a volatile memory, a non-volatile memory, a cache memory, a buffer, a short term memory unit, a long term memory unit, or other suitable memory units or storage units. Memory 120 may be or may include a plurality of, possibly different memory units. Memory 120 may be a computer or processor non-transitory readable medium, or a computer non-transitory storage medium, e.g., a RAM.

Executable code 125 may be any executable code, e.g., an application, a program, a process, task or script. Executable code 125 may be executed by controller 105 possibly under control of operating system 115. For example, executable code 125 may be an application for online placing of buying offers as further described herein. Although, for the sake of clarity, a single item of executable code 125 is shown in FIG. 1, a system according to some embodiments of the invention may include a plurality of executable code segments similar to executable code 125 that may be loaded into memory 120 and cause controller 105 to carry out methods described herein.

Storage system 130 may be or may include, for example, a flash memory as known in the art, a memory that is internal to, or embedded in, a micro controller or chip as known in the art, a hard disk drive, a CD-Recordable (CD-R) drive, a Blu-ray disk (BD), a universal serial bus (USB) device or other suitable removable and/or fixed storage unit. Content may be stored in storage system 130 and may be loaded from storage system 130 into memory 120 where it may be processed by controller 105. In some embodiments, some of the components shown in FIG. 1 may be omitted. For example, memory 120 may be a non-volatile memory having the storage capacity of storage system 130. Accordingly, although shown as a separate component, storage system 130 may be embedded or included in memory 120.

Input devices 135 may be or may include any suitable input devices, components or systems, e.g., a detachable keyboard or keypad, a mouse and the like. Output devices 140 may include one or more (possibly detachable) displays or monitors, speakers and/or any other suitable output devices. Any applicable input/output (I/O) devices may be connected to computing device 100 as shown by blocks 135 and 140. For example, a wired or wireless network interface card (NIC), a universal serial bus (USB) device or external hard drive may be included in input devices 135 and/or output devices 140. It will be recognized that any suitable number of input devices 135 and output device 140 may be operatively connected to computing device 100 as shown by blocks 135 and 140. For example, input devices 135 and output devices 140 may be used by a technician or engineer in order to connect to an SEU (that may be or may include computing device 100), download data from an SEU, read, or be presented with, data of the SEU, configure the SEU, update software and the like.

A system according to some embodiments of the invention may include components such as, but not limited to, a plurality of central processing units (CPU) or any other suitable multi-purpose or specific processors or controllers (e.g., controllers similar to controller 105), a plurality of input units, a plurality of output units, a plurality of memory units, and a plurality of storage units. A system may additionally include other suitable hardware components and/or software components. In some embodiments, a system may include or may be, for example, a plurality of components that include a respective plurality of central processing units, e.g., a plurality of SEUs as described, a plurality of SEUs embedded in an on board, system or network, a plurality of chips, FPGAs or SOCs, a plurality of computer or network devices, or any other suitable computing device. For example, a system as described herein may include one or more devices such as server 110.

According to some embodiments, one or more databases 10-50 may be databases related to different organizations and may include various types of data.

For example, a first database 10 may be related to building and planning committees and may include urban renovation data, including for example: areas (e.g., buildings, streets, neighborhoods, etc.) selected for urban renovation projects, criteria for selection of such areas (e.g. age of buildings, location etc.), the maximum permitted floor-area ratio that may be added to buildings according to renovation plans, the maximal number of floors permitted to be added, specific requirements imposed by the building and planning committees (e.g. location of multiple-story buildings and edifices, etc.).

In another example, a second database 20 may be related to a certain municipality and may include architectural data relating to a specific area (e.g., a city, a neighborhood, etc.). The architectural data may include data related to the structure of existing buildings, including for example: the total area of each lot, the total floor-area ration of each building, the number of floors in each building, the number of apartments, the size of each apartment, layout plans for each building, detailed construction plans of each building, required building materials, and the like.

In yet another example, a third database 30 may be related to the municipality and/or the building and planning committee and may include data related to development rights and requirements. For example, database 30 may include the maximal permitted floor-area building ratio, the maximal permitted number of floors, parking space requirements, minimal required distance from neighboring buildings and the like.

In yet another example, a forth database 40 may be related to governmental agencies and may include data related to taxation of urban renovation and building projects. In yet another example, a fifth database 50 may be related to a financial institute and may include funding costs for building projects. Other databases may include additional data such as building costs, project revenues and the like.

In some embodiments, at least some of databases 10-50 may be included in single database, for example, storage unit 120.

In some embodiments, server 110 may receive additional online information, including data from websites 60-70. For example: First website 60 may be an at least one real-estate agency website and may include prices of apartments. In another example, website 70 may be a social network website, in which users may enter prices and/or requests for buying/renting apartments or other properties.

In some embodiments, website 60 or 70 may be operated by server 110 and may provide users an interface for uploading information to server 110, including for example: addresses of interest, requests for buying properties and the like, and receive information from server 110, for example, feasibly estimations for an urban renovation project in the address or addresses and generated conceptual work plans for the project. Additionally or alternatively, at least one of website 60 or 70 may be operated by a different server and may be in communication with server 110.

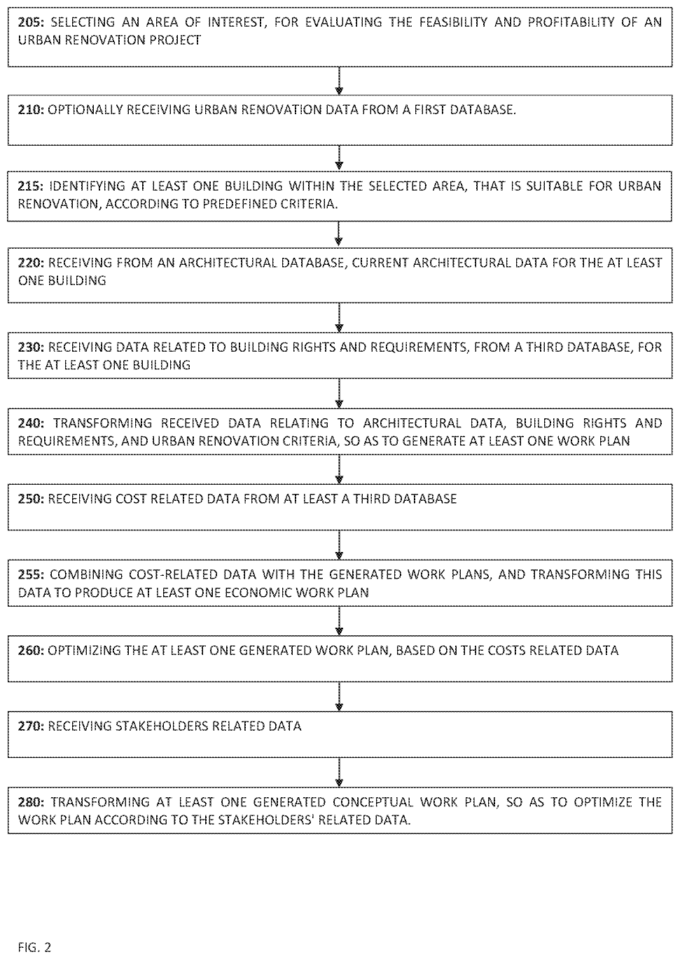

Reference is now made to FIG. 2 which is a flowchart of a method of generating conceptual work plans and/or optimizing urban renovation project plans according to some embodiments of the invention. The method of FIG. 2 may be conducted by server 110 of system 100. For example, controller 105 may execute at least some of the operation of the method of FIG. 2 stored as codes in memory 120.

In operation 205, an area of interest may be selected, for evaluating an urban renovation project. This evaluation may include for example, an assessment of the feasibility and profitability of urban renovation projects, as explained further below. For example, a user logging into a website (e.g., websites 30 or 40) may select to look for an urban renovation project in a certain neighborhood of a certain city. The user may select one or more building for the evaluation process, for example, by pointing the buildings on the map, entering an address and the like.

In operation 210, the controller may receive urban renovation data related to at least one building within the area of interest, from a first database. The urban renovation data may include, for example: areas (e.g., buildings, streets, neighborhoods, etc.) selected for urban renovation projects, criteria for selection of such areas (e.g. age of buildings, location etc.), the maximum permitted floor-area ratio that may be added to buildings according to renovation plans, the maximal number of floors permitted to be added, specific requirements imposed by the building and planning committees (e.g. location of multiple-story buildings and edifices, etc.).

In operation 215, the controller may identify at least one building within the selected area of interest that is suitable for urban renovation. In some embodiments, the identification of the at least one building may be based upon comparing data relating to the at least one building with the urban renovation data received from the first database. For example: A municipality may have marked specific buildings as intended for renovation, and the controller may be configured to access the municipal database, to retrieve a list of such buildings within the selected area of interest.

In another example, a municipality may have set a predefined criteria, determining which buildings should be suitable for applying an urban renovation plan, including parameters such as the age of buildings, size of apartments, building materials, location etc. The controller may be configured to access the municipal database, to identify these criteria, and access at least one other database to obtain characteristics of individual buildings within the selected neighborhood with the predefined criteria, to generate a list of buildings that are suitable for urban renovation according to these criteria.

In some embodiments, the user that used a designated website (e.g., website 60) may enter an address, a name of a street, a name of a neighborhood and the like and controller 105 may determine whether the building in the exact address is suitable for urban renovation or if at least one other building in the street, neighborhood or city is suitable for urban renovation. Controller 105 may connect, via the internet, to a first database (e.g., first database 10) that may include urban renovation data. For example, controller 105 may compare the exact address, street or neighborhood to urban renovation areas included in governmental urban renovation plans received from a database related to governmental building and planning committees.

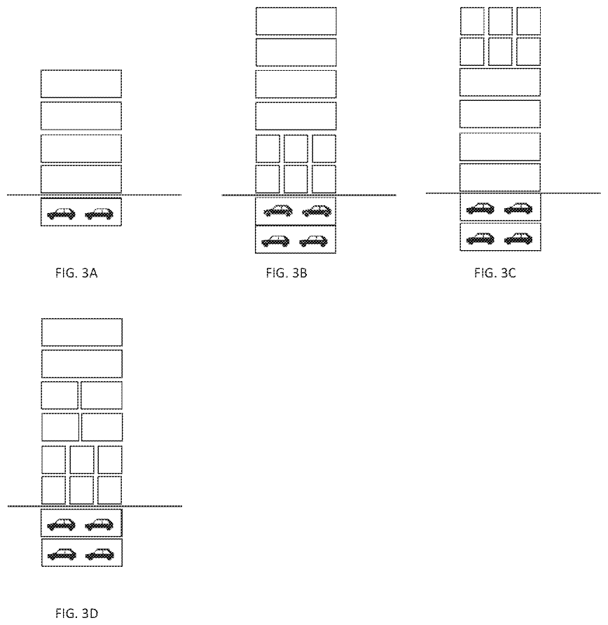

In operation 220, the controller may receive from a second database, current architectural data for the at least one building. For example, controller 105 may receive, via the internet, the current architectural data of a specific building or several buildings in a street or neighborhood that were identified as suitable for urban renovation. The architectural data may include, for example: the total area of the lot, the total built area of each building, the number of floors in each building, the number, location and area of apartments in each building, the number of parking spaces in each building, conceptual layout plans for each building (e.g.: as illustrated in FIG. 3A), and/or detailed plans for each building. In some embodiments, architectural data may further include information related to the location of each building with respect to its surroundings, including for example: a location of the building within a street or at a street crossing, relation of the building to the surrounding topography, positioning of the building in relation to adjacent buildings, and the like. In some embodiments, the architectural data may further include information related to the function of properties included in the at least one building, including for example: whether the building includes residential units, commercial areas (shops), offices, workshops, warehouses and the like.

The architectural data may be received from an architectural data base (e.g., entity 20 of FIG. 1), including for example: a building and planning committee or a municipality database.

FIG. 3A is an illustration of an example, for a conceptual layout plan of a building that has been identified as suitable for urban renovation, prior to the renovation project undertaking. The building has 4 floors with one large apartment in each floor and one underground parking floor.

Referring back to FIG. 2, in operation 230, the controller may receive data related to development rights and requirements, from, for example, a third database, for the at least one building. Controller 105 may receive from third data base 30 development rights that include at least one of: the maximal area permitted to be built on a certain lot, the maximal floor-area ratio, the maximal number of floors allowed, parking requirements, minimum required distance from neighboring buildings and the like. The third database may be a building and planning committee or a municipality database. The third database may be the same or may be different from the second database.

In operation 240, the controller may combine the received data related to at least one of: building rights and requirements, the received architectural data and the received urban renovation data for each building, and generate at least one conceptual work plan.

For example, controller 105 may combine the data acquired from the at least one database, as elaborated above, to generate work plans for renovation of an existing building, that may include: the number of floors that may be added, the additional square footage that may be added to each floor, the number and location of additional parking spaces, etc. In another example, controller 105 may be configured to amend a conceptual layout plan received from the architectural database, by adding floors, changing the layout of at least one apartment within at least one floor (e.g.: split or merge apartments within floors), adding parking spaces and the like, based on the development rights and requirements received and the urban renovation data.

Alternately, controller 105 may be configured to generate building plans that may be used to construct a completely new building that would replace the existing building according, for example, to the development rights and requirements and the urban renovation data.

In some embodiments, when more than one building is involved in the urban renovation project, the generated work plans may include transferring some of the development rights from a first building to a second building or even for building a new building on a vacant lot.

In some embodiments, the work plans may include at least part of: the total built area, the number of floors, the number of apartments in each floor, the area of each apartment, optional building additions such as balconies that may be added to the apartments, service areas (e.g., elevator, entrance, storage rooms, etc.), the number and location of parking spaces of the at least one building, and the like.

FIG. 3B depicts an exemplary work plan, generated for a building such as the building of FIG. 3A, according to some embodiments of the invention. The conceptual work plan illustrated in FIG. 3B may be generated after considering the received data related to building rights and requirements and the urban renovation data. The new building may include, for example: two additional floors and an additional parking floor. In Furthermore, the work plan may include dividing existing apartments into smaller apartments. In some embodiments, the conceptual plans may further include commercial areas (e.g., stores and offices) that may be added or included in the at least one building.

In some embodiments, the work plans may include detailed building plans for each floor in the at least one building, including for example: construction plans, electricity plans, water and drainage plans, roofing plans, electricity plans, etc.

In operation 250, the controller may receive cost-related data from at least a forth database. For example, controller 105 may receive from at least forth database 40 and/or fifth database 50 costs related data that may include building costs, data related to taxation (e.g., VAT, development tax, income taxes, property tax and the like), funding costs, project revenues and the like.

In operation 255 the controller may combine the cost-related data with the generated work plans, and produce at least one economic plan. In some embodiments the at least one economic plan may include separate economic information pertaining to the perspective of different stakeholders, such as tenants, apartment owners, landlords, building contractors, building entrepreneurs and the like. For example, the economic plan may include information relating to the economic feasibility and profitability of a potential urban renovation project, from various data sources, including contractor's databases and websites, real-estate agency websites, real-estate advertisement and trading databases and websites, etc. Real-estate entrepreneurs may utilize this data to evaluate the feasibility of a potential urban renovation project, or compare the profitability of two or more projects.

In some embodiments, the economic plan may include information relating to the cost of renovation in relation to an expected rise in rent income. For example, the controller may obtain from real-estate websites information relating to rent prices in the vicinity, pertaining to buildings before and after renovation. Accordingly, landlords may evaluate the cost of renovation in view of a present rent income, and an expected future rent income after renovation.

In some embodiments, the economic plan may include information related to the property's valuation, prior to renovation and following the renovation, and enable apartment owners to evaluate the profitability of conducting renovation in view of expected rise in their property's value, etc.

In some embodiments, the economic plan may include evaluating whether compensation is due to one or more of the stakeholders, evaluate the compensation cost, and compensation alternatives. For example, owners of a roof apartment may require compensation in order to accept a renovation plan that would add additional floors over theirs. Such compensation may be calculated for example by valuating the property before and after renovation through on-line real-estate databases and websites (e.g.: real-estate agency websites), and providing due compensation either as a payment or as additional footage to their apartment.

In some embodiments, the cost-related data may include socioeconomic data related to the population in the area (e.g., average income, number of children per family, divorce rate in an area and the like) that includes the at least one building. The cost-related data may be received from a plurality of databases, including for example: information regarding taxation from governmental databases, building costs from databases of construction companies and real-estate agencies, funding costs and revenues from databases of financial institutes and the like. In some embodiments, the system may further combine socioeconomic data as elaborated above, to generate an economic plan that may include an evaluation of socioeconomic parameters. The evaluation may pertain to the population before, during and after applying an urban renovation project. These parameters include, for example: the population's ability to withstand payments, the population's standard of living, the expected influx of population to the renovated area, the rate of an expected rise in property value due to such influx, etc.

In some embodiments, the cost-related data may further include prices of at least one of: apartments, shops, warehouses and offices in an area comprising the at least one building. In some embodiments, the cost-related data may include rental fees of at least one of: apartments, shops, warehouses and offices in an area comprising the at least one building. In some embodiments, the prices and/or rental fees may be received from websites (e.g., websites 60 or 70), such as, real-estate agencies' websites and commercial social networks. In some embodiments, controller 105 may update the cost-related data in real time following prices of current deals received from the real-estate agencies' websites and commercial social networks.

In some embodiments, the system may further be configured to assess the profitability and feasibility of a renovation work-plan by combining urban renovation data with cost-related data and demographic data, and generating at least one economic plan that includes a prediction of prices and/or rental fees of properties (e.g., apartments, shops and offices) in the area in the future, for example, at the end of the building process, after 3-5 years, etc.

Manual combination of such non-related data may require individuals to access multiple, non-related sources, and may prove to be unfeasible for individuals and systems that are not specifically configured for this task. Moreover, as demographic data, urban planning data, and cost-related data are interconnected, and have a mutual effect over each other, the analysis of profitability and feasibility requires a system that is configured to produce a profitability assessment iteratively, taking in all types of data (e.g. cost-related data, demographic data and urban renovation data) into account.

According to some embodiments, the method may include: receiving (e.g. from a municipal database or website) data related to existing buildings, including buildings that are currently under construction, and buildings that are about to be built in the vicinity (e.g., in the same street, neighborhood, city, neighboring city etc.) The data may be related to existing buildings and to buildings that are about to be built in the area may be received from building and planning committees, municipality databases, from websites promoting building projects in the area, from individual users, and the like. In some embodiments, a data may further be analyzed to determine the amount of real estate properties that will be added to the market in the future, after the current construction is done. A demographic information may further be obtained from at least one online website and/or database, related to at least one of: population growth, population influx and/or outflow, average income of the population, etc. At least part of the obtained data (e.g.: the demographic information, data relating to addition of real-estate properties, and cost-related data) may be combined; and the combined data may be analyzed to estimate how the prices and/or rental fees in the area may change in the near future (e.g. in the next 3-4 years), and assess the feasibility and/or profitability of the urban renovation project. According to some embodiments, the analysis of the combined data may be performed by a Machine Learning (ML) algorithm, that is configured to obtain the input data (e.g.: demographic, cost, and urban planning), and produce an assessment of profitability and/or feasibility.

In operation 260, the controller may be configured to iteratively optimize the generated work plans, based on at least one of the cost-related data, urban renovation data and demographic data. For example, Controller 105 may optimize the work plans (e.g., the plan in FIG. 3B) by iteratively producing a plurality of alternative work plans, generating respective economic plans that assess the profitability of each alternative work plan as explained above, and selecting at least one work plan from the plurality of work plans, that is optimal according to at least one criterion (e.g.: profit, duration of building, etc.).

The iterative optimization process of a work plan and a respective economic plan requires extracting a variety of data elements from multiple, non-related sources, analyzing the mutual effect and interconnections of these data elements and iteratively optimizing the work plans and economic plans. This process is not feasible manually, and may not be performed by a system that is not specifically configured for this task.

For example, controller 105 may: receive from a user at least one optimization criterion for optimizing a work plan (e.g.: cost, profit, expected property valuation, expected rent revenue, etc.) and a optimization criterion threshold (e.g.: a minimal required profit of P percent after Y years). Controller 105 may generate a plurality of alternative work plans, such as the alternative work plans illustrated in FIGS. 3C and 3D and may further obtain cost-related data, including for example: the cost of building, taxation and funding costs for each work plan. Additionally or alternatively, the controller may obtain demographic, and/or socioeconomic data relating to each work plan (e.g.: newly married couples may be attracted to small apartments, young families may be attracted to larger apartments, etc.). In some embodiments, controller 105 may combine the data relating to the alternative generated work plans (e.g. urban renovation data, cost-related data and demographic data) and may generate at least one economic plan, associated with at least one alternative work plan. According to some embodiments, the at least one economic plan may include an assessment of the work plan in relation to the at least one optimization criterion. For example, the economic plan may include a prediction of prices and/or rental fees of properties as explained above. In another example, the economic plan may include an assessment of the profitability and/or feasibility of renovation according to the alternative work-plan, as explained above.

According to some embodiments, if an optimization criterion threshold is met according to an assessment at least one economic plan (e.g. an economic plan predicts a required profit of P percent after Y years), then controller 105 may select the at least one alternative work plan, according to the at least one predefined criterion. Otherwise, controller 105 may be configured to continue to generate and analyze alternative work plans, until the optimization criterion threshold is met.

In operation 270, the controller may receive data relating to stakeholders from at least a fifth database, including at least one of: a currently built area for each stakeholder, floor-area ratio for each stakeholder, a common area (e.g., elevators, stairways, garbage rooms, etc.) in the at least one building that belongs to all stakeholders and the like. In some embodiments, the stakeholders' related data may further include compensation for all the stakeholders' that may be required to look for substitute accommodation during renovation. The compensation may include direct payment, allocation of additional area in the at least one building, an alternative apartment, additional commercial areas and the like.

In operation 280, embodiments may include optimizing, by the controller, the generated conceptual work plan based on the stakeholders' related data, and/or according to the stakeholder's point-of-view. For example, controller 105 may be configured to optimize the generated work plans according to the welfare of apartment owners and provide maximal footage for each apartment under a constraint of maximal price.

According to some embodiments, controller 105 may be configured to generated work plans that are optimized according to parameters of equality among stakeholders, may take into account required compensation for specific stakeholders. For example, individuals owning an apartment in the fourth and last floor of the building illustrated in FIG. 3A may oppose an urban renovation project plan that would add additional floors above their apartments. Controller 105 may generate a plurality of alternative conceptual work plans, and assess the profitability for each stakeholder, for each work plan, as explained above. Controller 105 may then select a work plan that is characterized by a minimal level of inequality in profit among different stakeholders. Alternatively, controller 105 may produce a work plan that may include an alternative form of compensation, including a payment, an additional parking space, or an additional smaller apartment, in order to compensate the opposing individuals, according to the assessed inequality in profit. In some embodiments, controller 105 may suggest the compensation prior to any opposition, in order to avoid the opposition. Accordingly, the conceptual plans may inherently include the compensation.

In some embodiments, the method of FIG. 2 may include an ongoing process of updating of the conceptual work plans when at least one of: the urban renovation data, architectural data, data related to development rights and requirements, cost-related data and stakeholders-related data is updated in any one of the databases. Controller 105 may further be configured to monitor the influence of such update on any parameter of the work plans and/or economic plans generated by the system.

In some embodiments, the method of FIG. 2 may further include selecting, by a user at least one of a preferred work plan and a preferred economic plan, and producing a tender from the selected plans, for implementing the renovation and/or reconstruction plans. The tender may include receiving offers from a plurality of construction companies for constructing the at least one building according to the work plans, and selecting the best offer based on predetermined parameters. The predetermined parameters may be those of costs, delivery time, quality demands and the like.

System 100 and the method of FIG. 2 may allow stakeholders (e.g., landlords, tenants, apartment owners and the like) to cooperate in management of urban renovation projects, with the benefit of maximal transparency for all the stakeholders. For example, system 100 may allow stakeholders from more than one building to be grouped together for a single urban renovation project if the grouping may benefit the urban renovation project. For example, apartment owners from two adjacent buildings may join forces in order to lower building costs.

The embodiments of FIG. 2 may further include receiving from a plurality of stakeholders associated with a single urban renovation project, for example, several tenants (e.g., apartment owners) in a building or two adjacent buildings, a request for a feasibility estimation for the urban renovation project. Controller 105 may receive from a first group of stakeholders the request, and produce at least one economic plan, depicting the costs and revenues for each stakeholder. In some embodiments, controller 105 may produce additional economic plans that depict the economic impact of an urban renovation project on at least one stakeholder beyond the first group (e.g. a projection of the at least one stakeholder's property value, in view of the upcoming project). Some embodiments may include presenting on a website (e.g., website 60) operated by system 100, the economic plans, including the expected and/or current costs and revenues for each stakeholder. Some embodiments, may include receiving a consent to participate in the urban renovation project, from at least some of the stakeholders, via the website.

Some embodiments may further include analyzing the feasibility of urban renovation projects in an entire area, such as an entire block, neighborhood or city.

Controller 105 may identify all the buildings in a predefined entire area that are suitable for urban renovation projects, and may consequently execute at least some of operations 220-280 for all the identified buildings. Controller 105 may then produce at least one work plan and economic plan respective of the identified buildings, including for example the cost efficiency, profitability and/or feasibility of urban renovation projects in the entire area. The economic plan may, for example, be presented in a website operated by system 100. For example: the controller may: divide the buildings to several groups based for example, upon the cost and/or complexity of the urban renovation project for each building; assign each group with a color, and displayed the entire area as a colored map marker; and enable municipality officials to prioritize various urban renovation projects in the area according to the assigned colors.

In some embodiments controller 105 may reactive, infrastructure data from an additional database (e.g., database six) or from databases 10-50. The infrastructure data may include, streets, location of schools and clinics, location of sewer and drain lines, water lines, electricity lines and the like. In some embodiments, controller 105 may be configured to combine the infrastructure data with data acquired from at least one source, as elaborated above (e.g. data related to development rights and requirements, data related to cost, data related to urban renovation plans, data originating from municipalities, data originating from building and planning committees, etc.) , and transform the infrastructure data so as to generate infrastructure work plans for the area at which the urban renovation projects are to be conducted. For example, if an urban renovation project includes a plurality of buildings in a specific neighborhood as suitable for renovation, controller 105 may generate at least one infrastructure work plan for adding public buildings and services such as schools and clinics, and renovate streets, sewer lines, water lines, electricity lines etc. to support an expected change (e.g., an increase) in population following the urban renovation project.

In some embodiments, system 100 may produce economic plans that may include development rights attributed to specific stakeholders. The system may further enable users to buy or sell such development rights to other users, according to their manifestation in the economic plans. For example, controller 105 may operate on website 60 a marketplace for development rights as a virtual market or as an auction.

While certain features of the invention have been illustrated and described herein, many modifications, substitutions, changes, and equivalents will now occur to those of ordinary skill in the art. It is, therefore, to be understood that the appended claims are intended to cover all such modifications and changes as fall within the true spirit of the invention.

1. A method of generating building work plans, comprising:
selecting an area for evaluating an urban renovation project therein;
receiving, by a controller, urban renovation data from a first database;
identifying, by the controller, at least one building within the selected area, that is suitable for urban renovation by comparing data related to the at least one building with the urban renovation data;
receiving, by the controller, from a second database, current architectural data for the at least one building;
receiving, by the controller, data related to building rights and requirements, from a third database, for the at least one building; and
generating, by the controller, at least one work plan from the received data.

2. The method according to claim 1, wherein the urban renovation data includes at least one of: areas selected for urban renovation projects; criteria for selection of these areas; a maximal permitted floor-area ratio that may be added to buildings according to renovation plans; a maximal number of floors permitted to be added according to renovation plans; and specific requirements imposed by building and planning committees.

3. The method according to claim 1, wherein the data related to building rights and requirements includes at least one of: the maximal floor-area ratio, the maximal number of floors allowed, parking space requirements, and minimal required distance from neighboring buildings.

4. The method according claim 1, wherein the at least one work plan comprises work plan data selected from a list consisting of: a determined number of floors in each of the at least one building; a determined number of apartments in each floor of the at least one building; a determined number and location of parking spaces of the at least one building; and detailed construction plans for one or more floors in the at least one building.

5. (canceled)

6. (canceled)

7. (canceled)

8. The method according to claim 1, further comprising:
receiving, by the controller, cost-related data from at least a fourth database;
combining the cost-related data with data of at least one generated work plan; and
analyzing, by the controller, the combined data to produce at least one economic plan, wherein said economic plan comprises economic information pertaining to the perspective of different stakeholders, selected from a list comprising tenants, apartment owners, landlords, building contractors and building entrepreneurs.

9. The method according to claim 8, wherein the cost-related data is selected from a list consisting of: building costs; data related to taxation; funding costs; project revenue; prices of apartments in an area comprising the at least one building; socioeconomic data relating to the population in the selected area.

10. (canceled)

11. The method according to claim 9, further comprising: updating the prices of the apartments in the area based on information received from at least one of a website and a social network.

12. The method according to claim 11, wherein the economic plan comprises economic information selected from a list consisting of: economic feasibility of a potential urban renovation project; economic profitability of at least one potential urban renovation project; cost of renovation; present rent income from a property; present valuation of a property; a prediction of expected rent income in the future, following an urban renovation; a prediction of expected evaluation of a property in the future, following urban renovation; an evaluation whether compensation is due to one or more of the stakeholders; an evaluation of the compensation cost at least one alternative for compensation; an evaluation of socioeconomic parameters pertaining to the population before, during and after applying an urban renovation project and development rights attributed to at least one specific stakeholder.

13. (canceled)

14. (canceled)

15. (canceled)

16. The method according to claim 12, wherein the socioeconomic parameters comprise at least one of: the population's ability to withstand payments; the population's standard of living; and an expected influx of population to the renovated area.

17. The method according to claim 8, further comprising:
receiving, by the controller, an update to the cost-related data; and
updating, by the controller, at least one generated work plan based on the updated cost-related data.

18. (canceled)

19. The method according to claim 1, further comprising optimization of the work plan according to at least one optimization criterion, wherein said optimization comprises:
receiving, by the controller, from a user, at least one optimization criterion;
generating, by the controller, a plurality of alternative work plans;
combining, by the controller, data of at least one alternative generated work plan with at least one of: respective cost-related data and respective socioeconomic data received from one or more databases;
generating, by the controller, at least one economic plan, associated with at least one alternative work plan, wherein said at least one economic plan comprises an assessment associated with the at least one optimization criterion; and
selecting, by the controller, at least one work plan of the plurality of alternative work plans according to assessment associated with the at least one optimization criterion.

20. The method according to claim 19, wherein optimizing, by the controller, at least one generated work plan further comprises:
combining the generated work plan with stakeholder-related data; and
producing, by the controller, at least one alternative work plan, that is optimized according to the stakeholder-related data.

21. (canceled)

22. The method according to claim 12, further comprising:
updating, by the controller, at least one cost-related data element;
iteratively optimizing, by the controller, at least one generated work plan for at least one building that is affected by the updating of the at least one cost-related data element; and
iteratively updating at least one economic plan according to data of at least one generated work plan.

23. The method according to claim 12, further comprising:
receiving, by the controller, a selection from a user of at least one of a preferred work plan and a preferred economic plan;
producing, by the controller, a tender from the selected plans, for implementing the work plans, and selecting the best offer based on predetermined parameters, wherein said parameters are selected among a list comprising cost, delivery time and quality demands.

24. (canceled)

25. The method according to claim 12, wherein the controller may be further configured to display the economic plans on a website and enable one or more users to trade on such development rights with one or more other users, according to their manifestation in the economic plans.

26. A system of generating building work plans, comprising:
at least one non-transitory memory medium, configured to store instructions to perform operations and/or processes; and
a controller associated with said memory medium, and configured to execute said instructions, wherein upon execution of the instructions, the controller is configured to:
receive from a user a selection of an area for evaluating an urban renovation project therein;
receive urban renovation data from a first database;
identify at least one building within the selected area, that is suitable for urban renovation by comparing data related to the at least one building with the urban renovation data;
receive from a second database, current architectural data for the at least one building;
receive data related to building rights and requirements, from a third database, for the at least one building; and
generate from the received data at least one work plan.

27. The system according to claim 26, wherein the at least one work plan comprises work plan data selected from a list consisting of: a determined number of floors in each of the at least one building; a determined number of apartments in each floor of the at least one building; a determined number and location of parking spaces of the at least one building; and detailed construction plans for one or more floors in the at least one building.

28. The system according to claim 26, wherein the controller is configured to iteratively optimize at least one generated work plan by:
updating at least one cost-related data element;
optimizing, by the controller, at least one generated work plan for at least one building that is affected by the updating of the at least one cost-related data element; and
iteratively updating at least one economic plan according to data of at least one generated work plan.
